(19) United States
(12) Patent Application Publication
(10) Pub. No.: US 2024/0365525 A1
(43) Pub. Date: Oct. 31, 2024

(54) SYSTEM, APPARATUS AND METHOD FOR MOUNTING COMPONENT

(71) Applicant: Hanwha Precision Machinery Co., Ltd., Changwon-si (KR)

(72) Inventor: Han Su Choi, Changwon-si (KR)

(73) Assignee: Hanwha Precision Machinery Co., Ltd., Changwon-si (KR)

(21) Appl. No.: 18/731,972

(22) Filed: Jun. 3, 2024

Related U.S. Application Data
(63) Continuation of application No. PCT/KR2022/021168, filed on Dec. 23, 2022.

(30) Foreign Application Priority Data
Jan. 18, 2022 (KR) 10-2022-0007287

(51) Int. Cl. H05K 13/08; H05K 13/04

(52) U.S. Cl. CPC H05K 13/085; H05K 13/046; H05K 13/0882

(57) ABSTRACT

An apparatus for mounting a component to a printed circuit board including: a head including a plurality of nozzles; a driver configured to move the head; a feeder base including a plurality of slots in which feeders are provided; and a controller configured to: receive task information, control the head and the driver according to the task information, and determine a predicted task time to complete a task according to the task information, where the controller is configured to determine the predicted task time based on disposition information of the feeders among the plurality of slots.

### CROSS-REFERENCE TO RELATED APPLICATION(S)

This application is a bypass continuation application of International Application No. PCT/KR2022/021168, filed on Dec. 23, 2022, in the Korean Intellectual Property Receiving Office, which is based on and claims priority to Korean Patent Application No. 10-2022-0007287, filed on Jan. 18, 2022, in the Korean Intellectual Property Office, the disclosures of which are incorporated by reference herein in their entireties.

### BACKGROUND

### 1. Field

The present disclosure relates to a system, apparatus, and method for mounting a component, and more particularly, to a system, apparatus, and method for mounting a component that may calculate a predicted task time by considering slots where feeders are previously disposed.

### 2. Description of Related Art

The surface mounting technology (SMT) refers to technology of attaching a component that may be mounted on a surface of a printed circuit board (“PCB” or “board”).

An SMT process refers to technology of printing solder paste on a PCB, mounting various surface mounting devices (SMDs) on the printed circuit board using a mounter apparatus, and then passing the printed circuit board on which the surface mounting devices are mounted through a reflow oven to bond the printed circuit board and leads of the surface mounting devices to each other.

A component mounting task by the SMT process may be performed by an apparatus for mounting a component. In order to produce one completed printed circuit board, a plurality of apparatuses for mounting a component may be disposed in a line to form one SMT line. The printed circuit board may sequentially pass through the plurality of apparatuses for mounting a component included in the SMT line, and corresponding components may be mounted by the respective apparatuses for mounting a component.

Each of the plurality of apparatuses for mounting a component may perform an individual task, and when a task time by some apparatuses for mounting a component is longer than a task time by the other apparatuses for mounting a component, an entire task time may increase.

Accordingly, an device that schedules a task of each apparatus for mounting a component so as to shorten an entire task time by the plurality of apparatuses for mounting a component has been demanded.

### SUMMARY

Provided are a system, apparatus, and method for mounting a component that may calculate a predicted task time based on slots where feeders are previously disposed.

Additional aspects will be set forth in part in the description which follows and, in part, will be apparent from the description, or may be learned by practice of the presented embodiments.

According to an aspect of the disclosure, an apparatus for mounting a component may include: a head including a plurality of nozzles; a driver configured to move the head; a feeder base including a plurality of slots in which feeders are provided; and a controller configured to: receive task information, control the head and the driver according to the task information, and determine a predicted task time to complete a task according to the task information, where the controller is configured to determine the predicted task time based on disposition information of the feeders among the plurality of slots.

The disposition information of the feeders may include: information on first slots among the plurality of slots in which first feeders are provided in a first state; and information on second slots among the plurality of slots in which second feeders are configured to be provided in a second state after the first state.

The second slots in which the second feeders are configured to be provided in the second state may be selected by a user.

The controller may be further configured to determine a pickup pattern of the head based on one or more groups of the first slots in which the first feeders are provided.

The controller may further configured to determine the predicted task time based on the second slots in which the second feeders are configured to be provided relative to the first slots in which the first feeders are provided.

The feeders may include a plurality of components, and the controller may be further configured to determine the predicted task time based on information including: simultaneous adsorption information on whether the head adsorbs a plurality of components simultaneously according to the disposition information of the feeders among the plurality of slots; nozzle exchange information on exchanging the plurality of nozzles included in the head with other nozzles; and a moving distance of the head between a board and a slot where a feeder is disposed among the plurality of slots.

The controller may be further configured to: generate a first algorithm in which the components are adsorbed to a maximum number of nozzles, generate a second algorithm in which a minimum number of nozzles are exchanged, generate a third algorithm in which the moving distance of the head is a minimum, and determine the predicted task time according to the first algorithm, the second algorithm, and the third algorithm.

The controller may be further configured to: determine the predicted task time based on the disposition information of the feeders among the plurality of slots and at least one of the simultaneous adsorption information, the nozzle exchange information, and the moving distance of the head.

According to an aspect of the disclosure, a system for mounting a component may include: a plurality of mounting apparatuses configured to perform tasks for mounting components on a printed circuit board; and a line managing apparatus configured to manage tasks for the plurality of mounting apparatuses, where the line managing apparatus is configured to generate task information for the plurality of mounting apparatuses and transmit the task information to the plurality of mounting apparatuses, and where the plurality of mounting apparatuses are configured to simulate using the received task information, determine a predicted task time as a simulation result, and transmit the determined task prediction time to the line managing apparatus.

The line managing apparatus may be configured to generate new task information based on a uniformity of a plurality of predicted task times received from the plurality of mounting apparatuses.

The plurality of mounting apparatuses may include: a feeder base including a plurality of slots in which feeders are provided; and a controller configured to: receive the task information, and determine a predicted task time to complete a task according to the task information, where the predicted task time is based on disposition information of the feeders among the plurality of slots.

The disposition information of the feeders may include: information on first slots among the plurality of slots in which first feeders are provided in a first state; and information on second slots among the plurality of slots in which second feeders are configured to be provided in a second state after the first state.

According to an aspect of the disclosure, a method for mounting a component on a printed circuit board by a mounting apparatus including a head and a feeder base with a plurality of slots in which feeders are provided, the method may include: receiving task information; and determining a predicted task time to complete a task according to the task information, where the predicted task time is based on disposition information of the feeders among the plurality of slots.

The disposition information of the feeders may include: information on first slots among the plurality of slots in which first feeders are provided in a first state; and information on second slots among the plurality of slots in which second feeders are provided in a second state after the first state.

The second slots in which the second feeders are provided in the second state may be selected by a user.

The determining of the predicted task time may include determining a pickup pattern of the head based on one or more groups of the first slots in which the first feeders are provided.

The determining the predicted task time may include determining the predicted task time based on the second slots in which the second feeders are provided in the second state relative to the first slots in which the first feeders are provided in the first state.

The determining the predicted task time may include determining the predicted task time based on information including: simultaneous adsorption information on whether the head adsorbs a plurality of components simultaneously according to the disposition information of the feeders among the plurality of slots; nozzle exchange information on replacing nozzles included in the head with other nozzles; and a moving distance of the head between a board and a slot in which a feeder is provided among the plurality of slots.

The determining the predicted task time may further include: generating a first algorithm in which the plurality of components are adsorbed to a maximum number of nozzles; generating a second algorithm in which a minimum number of nozzles are exchanged; generating a third algorithm in which the moving distance of the head is a minimum; and determining the predicted task time according to the first algorithm, the second algorithm, and the third algorithm.

The determining of the predicted task time may further include determining the predicted task time based on the disposition information of the feeders for the plurality of slots and to at least one of the simultaneous adsorption information, the nozzle exchange information, and the moving distance of the head.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a diagram illustrating a system for mounting a component according to an embodiment;

FIG. 2 is a flowchart illustrating a method for mounting a component according to an embodiment;

FIG. 3 is a diagram illustrating an apparatus for mounting a component according to an embodiment;

FIG. 4 is a diagram for describing a function of a conveyor according to an embodiment;

FIG. 5 is a diagram for describing an operation of a controller according to an embodiment;

FIG. 6 is a diagram illustrating that feeders are disposed in a feeder base according to an embodiment;

FIG. 7 is a diagram for describing pickup patterns of a head predictable based on feeders disposed in slot f and slot g in FIG. 6 according to an embodiment;

FIG. 8 is a diagram for describing pickup patterns of the head predictable based on feeders disposed in slot n, slot p, and slot r in FIG. 6 according to an embodiment;

FIG. 9 is a diagram for describing a final pickup pattern of the head according to an embodiment;

FIG. 10 is a diagram illustrating that feeders are disposed in the feeder base and additional feeders are waiting according to an embodiment;

FIG. 11 is a diagram for describing pickup patterns of the head predictable based on feeders disposed in slot f to slot j in FIG. 10 according to an embodiment; and

FIG. 12 is a diagram for describing pickup patterns of the head predictable based on feeders disposed in slot n to slot s in FIG. 10 according to an embodiment.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms. It is to be understood that singular forms include plural referents unless the context clearly dictates otherwise. The terms including technical or scientific terms used in the disclosure may have the same meanings as generally understood by those skilled in the art.

It will be understood that the terms “includes,” “comprises,” “has,” “having,” “including,” and/or “comprising,” when used in this specification, specify the presence of stated features, figures, steps, operations, components, members, or combinations thereof, but do not preclude the presence or addition of one or more other features, figures, steps, operations, components, members, or combinations thereof.

The term “or” includes any and all combinations of one or more of a plurality of associated listed items.

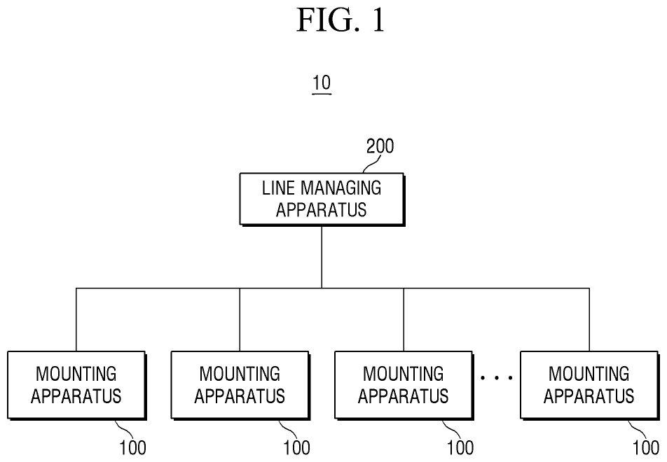

FIG. 1 is a diagram illustrating a system for mounting a component according to an embodiment.

Referring to FIG. 1, a system 10 for mounting a component may include an mounting apparatus 100 and a line managing apparatus 200.

The mounting apparatus 100 may perform a task for mounting a component on a printed circuit board (PCB) (hereinafter referred to as a board). The mounting apparatus 100 may mount the component on the board using surface mounting technology (SMT). The component may be a surface mount device (SMD).

The mounting apparatus 100 may print solder paste on a surface of the board, mount the component on the board, and then pass the board on which the component is mounted through a reflow oven to perform bonding between the board and leads of the component.

The mounting system 10 may include a plurality of mounting apparatuses 100. In order to produce one completed board, the plurality of mounting apparatuses 100 may perform tasks interworking with each other. The plurality of mounting apparatuses 100 may be disposed in a line to form one SMT line. The board may sequentially pass through the plurality of mounting apparatuses 100 included in the SMT line, and each mounting apparatus 100 may perform a component mounting task on the input board.

The line managing apparatus 200 may manage an interworking task for the plurality of mounting apparatuses 100. In order to complete one board, each mounting apparatus 100 may perform an individual task. For example, some of the plurality of mounting apparatuses 100 may perform the same task, and others of the plurality of mounting apparatuses 100 may perform different tasks. Alternatively, all of the plurality of mounting apparatuses 100 may perform different tasks. The line managing apparatus 200 may manage which task each mounting apparatus 100 should perform, and each mounting apparatus 100 may perform a task corresponding to a command of the line managing apparatus 200.

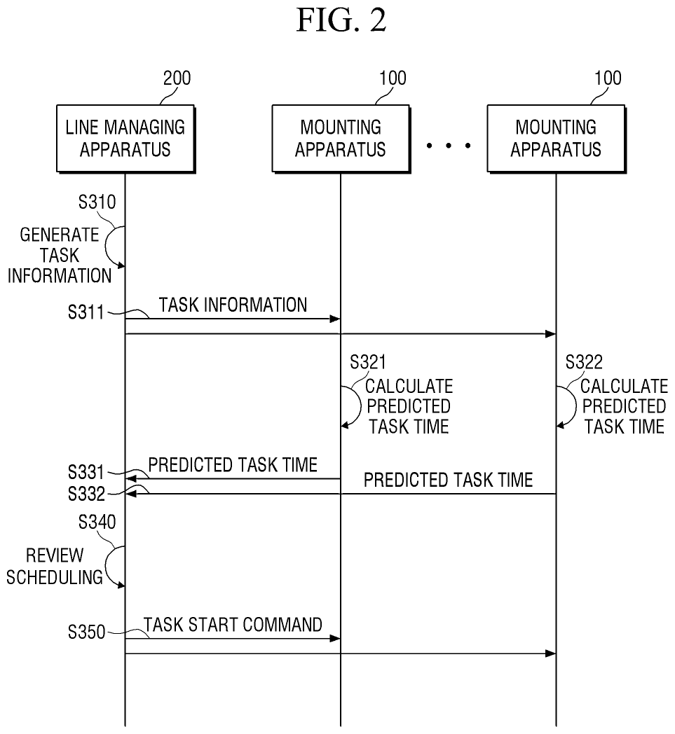

FIG. 2 is a flowchart illustrating a method for mounting a component.

Referring to FIG. 2, the line managing apparatus 200 may perform management for a task of the mounting apparatus 100, and the mounting apparatus 100 may perform a task corresponding to a command of the line managing apparatus 200. The plurality of mounting apparatuses 100 and the line managing apparatus 200 may be connected through a wired and/or wireless network.

The line managing apparatus 200 may include one or more processors, a memory, and a transmission interface for communicating with the plurality of mounting apparatuses 100.

First, the line managing apparatus 200 may schedule tasks for the plurality of mounting apparatuses 100. The line managing apparatus 200 may generate task information for each of the plurality of mounting apparatuses 100 (S310). For example, the task information may include information on which component should be mounted at which mounting point using which nozzle. The line managing apparatus 200 may generate task information in which a time required to complete one board is predicted as a minimum time. When the task information is generated, the line managing apparatus 200 may transmit the task information to each mounting apparatus 100 (S310).

Each mounting apparatus 100 may calculate a predicted task time according to the received task information (S321 and S322). The predicted task time may be a time predicted for the mounting apparatus 100 to complete a task according to the task information when the board is input to the mounting apparatus 100. The mounting apparatus 100 may perform a simulation using the received task information via a simulation program, and calculate the predicted task time as a result of the simulation. When the calculation of the predicted task time is completed, each mounting apparatus 100 may transmit the calculated predicted task time to the line managing apparatus 200 (S331 and S332).

The line managing apparatus 200 may review scheduling for each mounting apparatus 100 by referring to the predicted task time received from the mounting apparatus 100 (S340). For example, the line managing apparatus 200 may decide whether or not the predicted task times for the plurality of mounting apparatuses 100 are uniform. In this way, when a plurality of predicted task times are uniform, the line managing apparatus 200 may transmit a task start command to a mounting apparatus 100 (S350).

The mounting apparatus 100 that has received the task start command may perform the task according to the task information previously received.

On the other hand, when the plurality of predicted task times are not uniform according to a scheduling review result, the line managing apparatus 200 may generate new task information by rescheduling the tasks for the plurality of mounting apparatuses 100. For example, when a difference between the plurality of predicted task times exceeds a preset threshold value, the line managing apparatus 200 may generate new task information. Alternatively, when the greatest predicted task time of the plurality of predicted task times exceeds a preset threshold value, the line managing apparatus 200 may generate new task information by rescheduling the tasks for the plurality of mounting apparatuses 100.

The generated new task information may be transmitted to the mounting apparatus 100, and each mounting apparatus 100 may calculate a predicted task time according to the new task information and transmit the predicted task time to the line managing apparatus 200.

A series of processes from a process of generating the task information to a process of reviewing the scheduling as described above may be performed until the plurality of predicted task times are uniform to a predetermined degree, or the greatest predicted task time becomes a threshold value or less. Since the new task information is generated by referring to a new predicted task time, as repetitions are performed, the uniformity of the plurality of predicted task times may be gradually improved or the greatest predicted task time may be shortened.

A period from a point in time when the task information is generated to a point in time when the review of the scheduling is completed (hereinafter referred to as a task scheduling time) may be affected by a time required to calculate the predicted task time by each mounting apparatus 100 (hereinafter referred to as a calculation time). Calculation times by the plurality of mounting apparatuses 100 may be individually formed, and the task scheduling time may be affected by the greatest calculation time of a plurality of calculation times.

After transmitting the task information, the line managing apparatus 200 may not perform the review of the scheduling until the last predicted task time is received. In order to reduce the task scheduling time, the calculation time by each mounting apparatus 100 may be reduced.

As described later, the mounting apparatus 100 may include a feeder base including a plurality of slots. The mounting apparatus 100 may consider whether to use the slots in calculating the predicted task time. In this case, it may be considered whether to use unnecessary slots, and thus, the calculation time of the predicted task time may become long. The mounting apparatus 100 according to an embodiment of the present disclosure may consider only slots that are used or expected to be used, and thus, the predicted task time may be calculated more quickly.

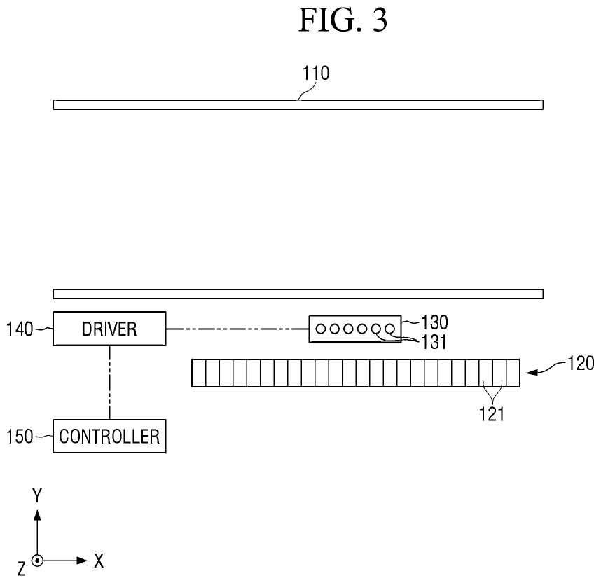

Hereinafter, a configuration and operation of the mounting apparatus 100 will be described in detail with reference to FIGS. 3 to 12.

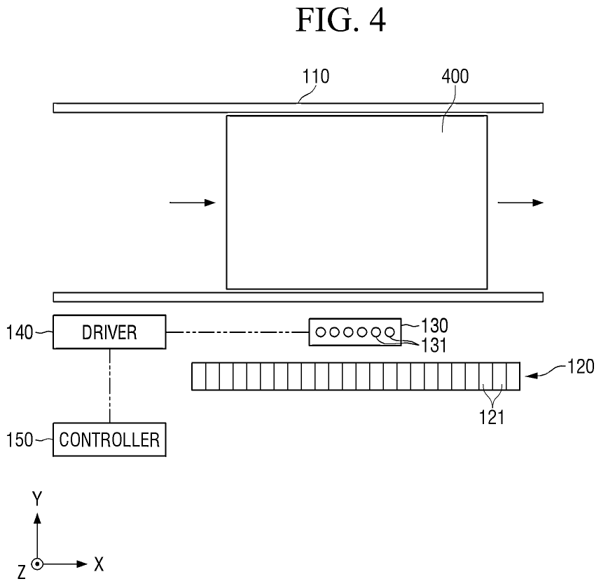

FIG. 3 is a diagram illustrating a mounting apparatus for mounting a component according to an embodiment of the present disclosure, and FIG. 4 is a diagram for describing a function of a conveyor.

Referring to FIG. 3, each of the plurality of mounting apparatuses 100 according to an embodiment of the present disclosure may include a conveyor 110, a feeder base 120, a head 130, a driver 140, and a controller 150.

The conveyor 110 may move a board (e.g., a PCB). Hereinafter, a moving direction of the board by the conveyor 110 is referred to as a first direction X, a direction parallel to the board and perpendicular to the first direction X is referred to as a second direction Y, and a direction perpendicular to the first direction X and the second direction Y is referred to as a third direction Z.

Referring to FIG. 4, the board 400 may be guided by the conveyor 110 to be moved to or from a task position. The conveyor 110 may sequentially move different boards 400 to or from the task position.

Referring to FIG. 3, the feeder base 120 may feed a component to a task space. The feeder base 120 may include a plurality of slots 121 where feeders may be disposed. One feeder may be disposed in one slot 121. The feeder may be installed with a reel including a plurality of components, and the components may be sequentially fed by an operation of the feeder.

The head 130 may mount the component on the board 400. To this end, the head 130 may include a plurality of nozzles 131. The head 130 may move in the task space. For example, the head 130 may move on a two-dimensional plane formed by the first direction X and the second direction Y. The head 130 may move to the feeder base 200 in order to collect the components or move to a position above a specific point of the board 400 in order to mount the component at the specific point.

The driver 140 may move the head 130. The head 130 may move between the board 400 and the feeder base 120 by a driving force of the driver 140. The driver 140 may be provided in the form of a gantry. The driver 140 may be characterized as a motor, including at least one stator and at least one rotor, configured to convert electrical energy into mechanical energy to move the gantry.

The controller 150 may control the driver 140 and the head 130. The driver 140 may operate according to a control command of the controller 150 to move the head 130. The head 130 may operate the nozzle 131 according to a control command of the controller 150 to adsorb the component from the feeder or mount the component on the board 400.

The controller 150 may be connected to the line managing apparatus 200 either through a wired network or wireless network. The controller 150 may receive task information from the line managing apparatus 200. In addition, the controller 150 may control the head 130 and the driver 140 according to the task information and calculate a predicted task time required to complete a task according to the task information.

The controller 150 may receive the task information from the line managing apparatus 200 and control the head 130 and the driver 140 according to the received task information. The controller 150 may calculate a predicted task time required to perform a mounting task according to the task information before controlling the head 130 and the driver 140 to perform the mounting task on the board 400. The controller 150 may predict a time from a time when the board 400 is input to the conveyor 110 to a time when all tasks on the board 400 are completed.

The controller 150 may transmit the calculated predicted task time to the line managing apparatus 200. In addition, when a task start command is received from the line managing apparatus 200, the controller 150 may control the head 130 and the driver 140 according to the task information to perform the component mounting task on the board 400.

The controller 150 may calculate the predicted task time by referring to disposition information of the feeders for the plurality of slots 121. When the predicted task time is calculated by considering all slots where the feeders are not disposed or are not to be disposed in the future, a time required to calculate the predicted task time may become long. According to the present disclosure, only slots where the feeders are disposed or are to be disposed in the future are considered, and thus, the time required to calculate the predicted task time may be shortened.

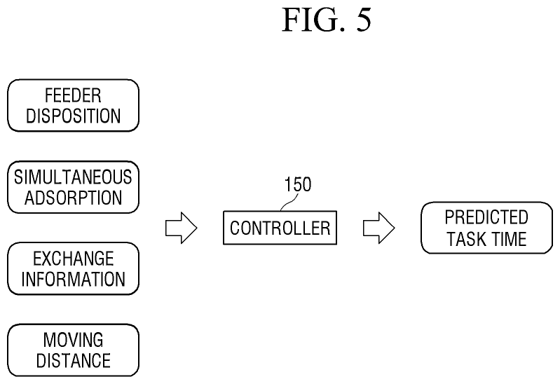

FIG. 5 is a diagram for describing an operation of a controller according to an embodiment.

The controller 150 may be physically implemented by analog and/or digital circuits including one or more of a logic gate, an integrated circuit, a microprocessor, a microcontroller, a memory circuit, a passive electronic component, an active electronic component, an optical component, and the like, and may implement or execute software and/or firmware to perform the functions or operations described herein.

Referring to FIG. 5, the controller 150 may calculate the predicted task time by referring to feeder disposition information, simultaneous adsorption information, nozzle exchange information, and a moving distance.

The feeder disposition information may include information on slots where feeders are disposed. In the present disclosure, the feeder disposition information may include pre-disposition information and post-disposition information. The pre-disposition information may refer to information on slots where feeders have been previously disposed among the plurality of slots 121 included in the feeder base 120. In other words, the pre-disposition information may refer to disposition information of first feeders among the plurality of slots in a first state. A component mounting task on the board 400 may be performed before a point in time when the predicted task time is calculated. In this case, the feeders may be disposed in some slots for a previous task. The pre-disposition information may be information on the slots where the feeders are disposed for the previous task.

The post-disposition information may refer to information on slots where feeders are to be disposed in the future among the plurality of slots 121 included in the feeder base 120. In other words, the post disposition information may refer to disposition information of second feeders among the plurality of slots in a second state. The second state may refer to a time period after the first state. Feeders have not yet been disposed in any of the plurality of slots 121 at the point in time when the predicted task time is calculated, but feeders that are to be disposed in any slots of the plurality of slots 121 in the future may be provided. The post-disposition information may be information on slots where corresponding feeders are to be disposed in the future (e.g., second state).

The controller 150 may calculate the predicted task time using the pre-disposition information and the post-disposition information. When there are feeders previously disposed in the slots, the controller 150 may calculate the predicted task time using only the pre-disposition information or using the post-disposition information together with the pre-disposition information. In this case, the controller 150 may calculate the predicted task time by considering that the head 130 moves to the slots 121 of the feeder base 120 according to the pre-disposition information or the post-disposition information and does not move to the other slots.

The simultaneous adsorption information refers to information regarding whether the head 130 may adsorb a plurality of components simultaneously. As the feeders may include the components, the simultaneous adsorption information may depend on the disposition information of the feeders among the plurality of slots. The simultaneous adsorption information may refer to information on how many components the head 130 which has moved to the feeder base 120 may adsorb simultaneously before moving to the board 400. The head 130 may include a plurality of nozzles 131. In calculating the predicted task time according to the task information, the controller 150 may generate an algorithm causing components to be adsorbed to as many nozzles 131 as possible and calculate the predicted task time according to the generated algorithm.

The nozzle exchange information refers to information on exchanging the nozzles included in the head 130 with other nozzles. Different nozzles may be used for each component. For example, nozzle 1 may be used to adsorb component 1, but nozzle 2 may be used to adsorb component 2. The controller 150 may exchange some of the nozzles installed in the head 130 with other nozzles appropriate for the components. In calculating the predicted task time according to the task information, the controller 150 may generate an algorithm causing as few nozzles 131 as possible to be exchanged and calculate the predicted task time according to the generated algorithm.

The moving distance refers to a distance of the head 130 moving between the board 400, which is a task target, and the slot where the feeder is disposed among the plurality of slots 121. In calculating the predicted task time according to the task information, the controller 150 may generate an algorithm causing the moving distance to be as short as possible and calculate the predicted task time according to the generated algorithm.

The controller 150 may calculate the predicted task time by referring to the feeder disposition information and additionally referring to at least one of the simultaneous adsorption information, the nozzle exchange information, and the moving distance. Alternatively, according to some embodiments of the present disclosure, the controller 150 may calculate the predicted task time by referring to only some of the feeder disposition information, the simultaneous adsorption information, the nozzle exchange information, and the moving distance or calculate the predicted task time by referring to all of the feeder disposition information, the simultaneous adsorption information, the nozzle exchange information, and the moving distance.

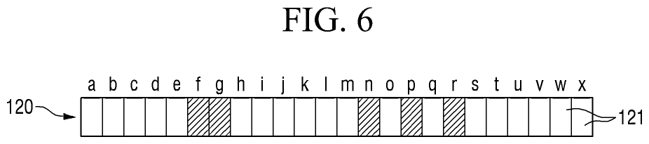

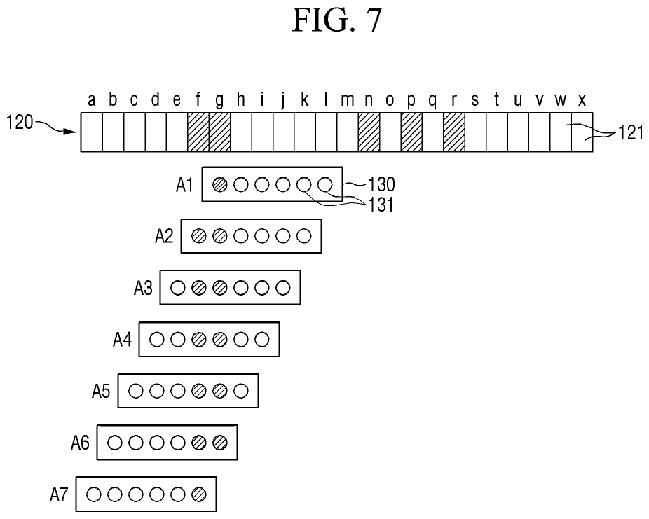

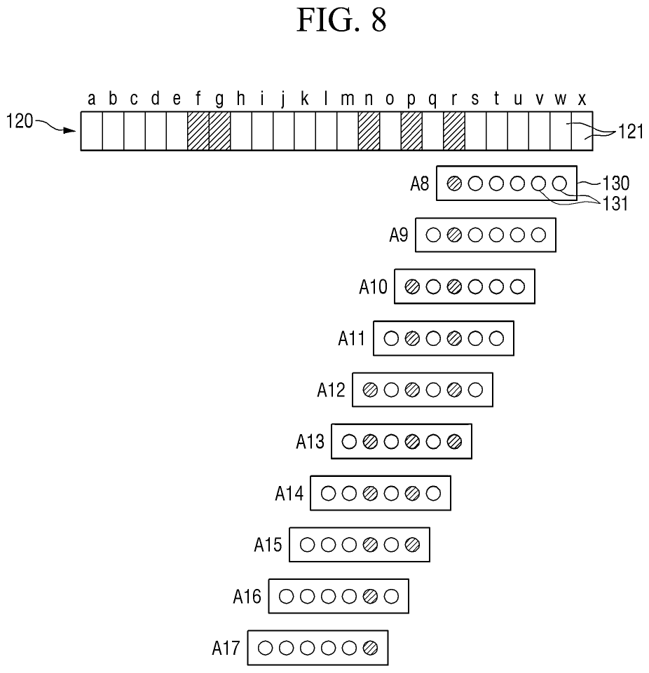

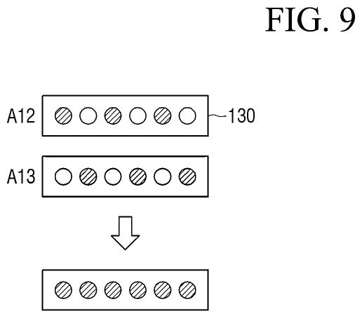

FIG. 6 is a diagram illustrating that feeders are disposed in a feeder base, FIG. 7 is a diagram for describing pickup patterns of a head 130 predictable based on feeders disposed in slot f and slot g in FIG. 6, FIG. 8 is a diagram for describing pickup patterns of the head predictable based on feeders disposed in slot n, slot p, and slot r in FIG. 6, and FIG. 9 is a diagram for describing a final pickup pattern of the head.

Referring to FIG. 6, the feeder base 120 may include slots where feeders are previously disposed.

Slots marked as white spaces among a plurality of slots 121 illustrated in FIG. 6 refer to slots where feeders are to be disposed, and slots marked as shades among the plurality of slots 121 refer to slots where feeders were previously disposed. FIG. 6 illustrates that feeders were previously disposed in slot f, slot g, slot n, slot p, and slot r. Hereinafter, the feeders disposed in slot f, slot g, slot n, slot p, and slot r are referred to as pre-disposition feeders.

The controller 150 may calculate the predicted task time by considering the slots where the feeders were previously disposed. In the present disclosure, the head 130 may include six nozzles 131. Accordingly, the controller 150 may calculate the predicted task time by considering adsorption ability of the six nozzles 131.

As illustrated in FIG. 6, the pre-disposition feeders may be disposed in a group in slot f and slot g, and may be disposed in a group in slot n, slot p, and slot r. Since a distance between both groups is a distance at which simultaneous adsorption by the six nozzles 131 may not be possible, the controller 150 may decide pickup patterns of the head 130 for each group.

FIG. 7 illustrates pickup patterns of the head 130 for a first group including slot f and slot g, and FIG. 8 illustrates pickup patterns of the head 130 for a second group including slot n, slot p, and slot r. In a pickup pattern of A1, the head 130 may adsorb a component disposed in slot g using the leftmost nozzle, and in a pickup pattern of A2, the head 130 may adsorb components disposed in slot f and slot g using the leftmost nozzle and a nozzle adjacent to the leftmost nozzle.

The controller 150 may calculate the predicted task time by considering all pickup patterns of A1 to A17. As illustrated in FIG. 9, when the pickup pattern of A12 and the pickup pattern of A13 are combined with each other, it may be possible to simultaneously adsorb components to all of the six nozzles 131. Accordingly, the controller 150 may calculate the predicted task time on the basis of adsorbing components of the feeders disposed in slot n, slot p, and slot r and performing a task.

Since the predicted task time is calculated by considering only the slots included in the first group and the second group rather than all the slots 121 included in the feeder base 120, a time required to calculate the predicted task time may be shortened.

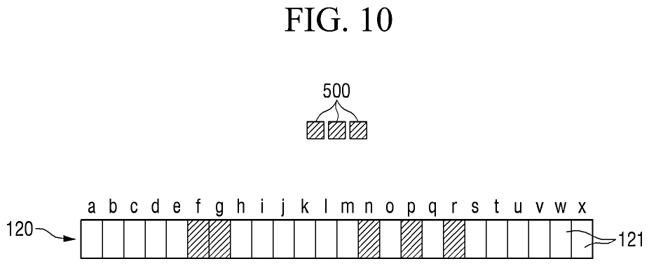

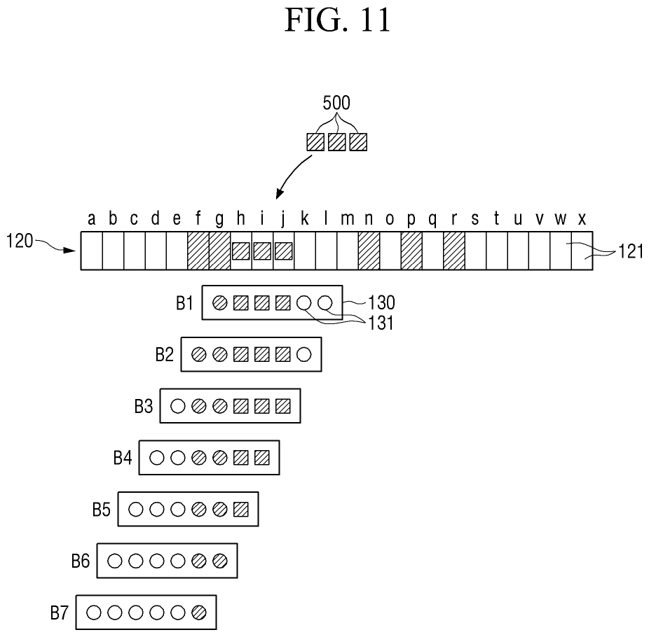

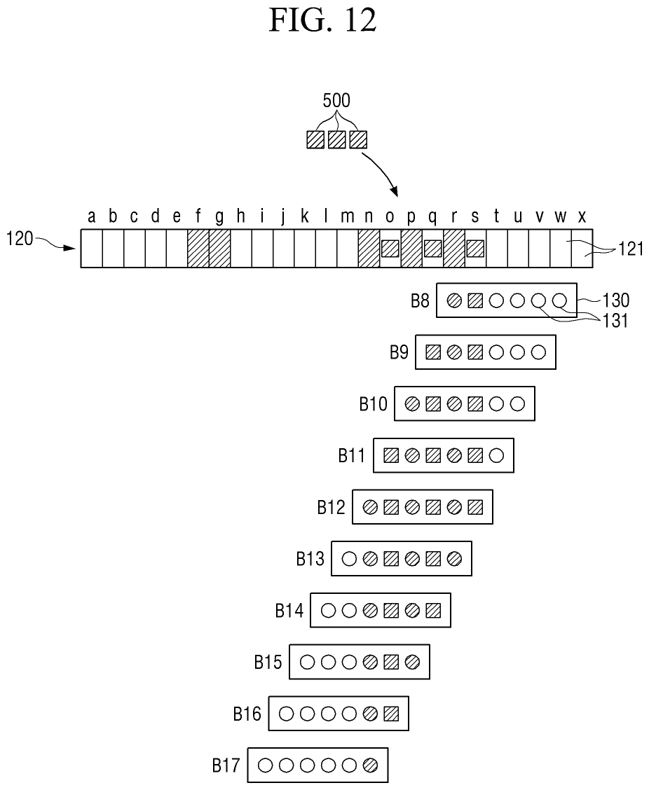

FIG. 10 is a diagram illustrating that feeders are disposed in the feeder base and additional feeders are waiting, FIG. 11 is a diagram for describing pickup patterns of the head predictable based on feeders disposed in slot f to slot j in FIG. 10, and FIG. 12 is a diagram for describing pickup patterns of the head predictable based on feeders disposed in slot n to slot s in FIG. 10.

Referring to FIG. 10, the feeder base 120 may include slots where feeders were previously disposed. In addition, separate feeders (hereinafter referred to as post-disposition feeders) 500 that are to be disposed in the future in any slots of a plurality of slots 121 included in the feeder base 120 may be provided.

Slots marked as white spaces among the plurality of slots 121 illustrated in FIG. 10 refer to slots where feeders are to be disposed, and slots marked as shades among the plurality of slots 121 refer to slots where feeders are previously disposed. FIG. 10 illustrates that feeders are previously disposed in slot f, slot g, slot n, slot p, and slot r. Hereinafter, the feeders disposed in slot f, slot g, slot n, slot p, and slot r are referred to as pre-disposition feeders.

The post-disposition feeder 500 may be disposed in any slots of the plurality of slots 121 where the pre-disposition feeders are not disposed. For example, a user may dispose the post-disposition feeders 500 in specific slots by referring to a scheduling result of the line managing apparatus 200.

The controller 150 may calculate the predicted task time by considering the slots where the feeders are previously disposed and the slots where the feeders are disposed later. According to an embodiment, the head 130 may include six nozzles 131, but is not limited thereto. Accordingly, the controller 150 may calculate the predicted task time by considering adsorption ability of the six nozzles 131.

As illustrated in FIG. 10, the pre-disposition feeders may be disposed in a group in slot f and slot g, and may be disposed in a group in slot n, slot p, and slot r. Since a distance between both groups is a distance at which simultaneous adsorption by the six nozzles 131 may not be possible, the controller 150 may decide pickup patterns of the head 130 for each group.

FIG. 11 illustrates pickup patterns of the head 130 for a first group including slot f and slot g, and FIG. 12 illustrates pickup patterns of the head 130 for a second group including slot n, slot p, and slot r. The controller 150 may calculate the predicted task time, assuming that the post-disposition feeders 500 are disposed adjacent to the slots of each group. FIG. 11 illustrates that the post-disposition feeders 500 are disposed in slot h, slot i, and slot j, and FIG. 12 illustrates that the post-disposition feeders 500 are disposed in slot o, slot q, and slot s. The controller 150 may consider that the post-disposition feeders 500 are disposed in slots different from those in dispositions of FIGS. 11 and 12 in calculating the predicted task time. Hereinafter, it will be described that the task prediction time may be calculated by considering only that the post-disposition feeders 500 are disposed in slot h, slot i, slot j, slot o, slot q, and slot s.

The controller 150 may calculate the predicted task time by considering all pickup patterns of B1 to B17. As illustrated in FIG. 12, in the case of the pickup pattern of B12, it may be possible to simultaneously adsorb components to all of the six nozzles 131 with one pickup operation. Accordingly, the controller 150 may calculate the predicted task time on the basis of adsorbing components of the feeders disposed in slot n to slot r and performing a task.

The post-disposition feeders 500 may be disposed in any slots where the pre-disposition feeders are not disposed. The controller 150 may calculate the predicted task time by considering that the post-disposition feeders 500 are disposed adjacent to the pre-disposition feeders in various manners.

With the system, apparatus, and method for mounting a component according to the present disclosure as described above, a time required to calculate a predicted task time may be shortened because the predicted task time is calculated by considering only slots where feeders are previously disposed.

The embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it is to be understood that the embodiments described above are illustrative rather than being restrictive in all aspects.

What is claimed is:

1. An apparatus for mounting a component, comprising:
a head comprising a plurality of nozzles;
a driver configured to move the head;
a feeder base comprising a plurality of slots in which feeders are provided; and
a controller configured to:
receive task information,
control the head and the driver according to the task information, and
determine a predicted task time to complete a task according to the task information,
wherein the controller is configured to determine the predicted task time based on disposition information of the feeders among the plurality of slots.

2. The apparatus for mounting a component of claim 1, wherein the disposition information of the feeders comprises:
information on first slots among the plurality of slots in which first feeders are provided in a first state; and
information on second slots among the plurality of slots in which second feeders are configured to be provided in a second state after the first state.

3. The apparatus for mounting a component of claim 2, wherein the second slots in which the second feeders are configured to be provided in the second state are selected by a user.

4. The apparatus for mounting a component of claim 2, wherein the controller is further configured to determine a pickup pattern of the head based on one or more groups of the first slots in which the first feeders are provided.

5. The apparatus for mounting a component of claim 4, wherein the controller is further configured to determine the predicted task time based on the second slots in which the second feeders are configured to be provided relative to the first slots in which the first feeders are provided.

6. The apparatus for mounting a component of claim 1, wherein the feeders comprise a plurality of components, and
wherein the controller is further configured to determine the predicted task time based on information comprising:
simultaneous adsorption information on whether the head adsorbs a plurality of components simultaneously according to the disposition information of the feeders among the plurality of slots;
nozzle exchange information on exchanging the plurality of nozzles included in the head with other nozzles; and
a moving distance of the head between a board and a slot where a feeder is disposed among the plurality of slots.

7. The apparatus for mounting a component of claim 6, wherein the controller is further configured to:
generate a first algorithm in which the components are adsorbed to a maximum number of nozzles,
generate a second algorithm in which a minimum number of nozzles are exchanged,
generate a third algorithm in which the moving distance of the head is a minimum, and
determine the predicted task time according to the first algorithm, the second algorithm, and the third algorithm.

8. The apparatus for mounting a component of claim 6, wherein the controller is further configured to:
determine the predicted task time based on the disposition information of the feeders among the plurality of slots and at least one of the simultaneous adsorption information, the nozzle exchange information, and the moving distance of the head.

9. A system for mounting a component, comprising:
a plurality of mounting apparatuses configured to perform tasks for mounting components on a printed circuit board; and
a line managing apparatus configured to manage tasks for the plurality of mounting apparatuses,
wherein the line managing apparatus is configured to generate task information for the plurality of mounting apparatuses and transmit the task information to the plurality of mounting apparatuses, and
wherein the plurality of mounting apparatuses are configured to simulate the received task information, determine a predicted task time as a simulation result, and transmit the predicted task time to the line managing apparatus.

10. The system for mounting a component of claim 9, wherein the line managing apparatus is further configured to generate new task information based on a uniformity of a plurality of predicted task times received from the plurality of mounting apparatuses.

11. The system for mounting a component of claim 9, wherein the plurality of mounting apparatuses respectively comprise:
a feeder base comprising a plurality of slots in which feeders are provided; and
a controller configured to:
receive the task information, and
determine the predicted task time to complete a task according to the task information, and
wherein the predicted task time is based on disposition information of the feeders among the plurality of slots.

12. The system for mounting a component of claim 11, wherein the disposition information of the feeders comprises:
information on first slots among the plurality of slots in which first feeders are provided in a first state; and
information on second slots among the plurality of slots in which second feeders are configured to be provided in a second state after the first state.

13. A method for mounting a component on a printed circuit board by a mounting apparatus comprising a head and a feeder base with a plurality of slots in which feeders are provided, the method comprising:
receiving task information; and
determining a predicted task time to complete a task according to the task information,
wherein the predicted task time is based on disposition information of the feeders among the plurality of slots.

14. The method for mounting a component of claim 13, wherein the disposition information of the feeders comprises:
information on first slots among the plurality of slots in which first feeders are provided in a first state; and
information on second slots among the plurality of slots in which second feeders are configured to be provided in a second state after the first state.

15. The method for mounting a component of claim 14, wherein the second slots in which the second feeders are provided in the second state are selected by a user.

16. The method for mounting a component of claim 14, wherein the determining of the predicted task time comprises determining a pickup pattern of the head based on one or more groups of the first slots in which the first feeders are provided.

17. The method for mounting a component of claim 16, wherein the determining the predicted task time further comprises determining the predicted task time based on the second slots in which the second feeders are provided in the second state relative to the first slots in which the first feeders are provided in the first state.

18. The method for mounting a component of claim 13, wherein the determining the predicted task time comprises determining the predicted task time based on information comprising:
simultaneous adsorption information on whether the head adsorbs a plurality of components simultaneously according to the disposition information of the feeders among the plurality of slots;
nozzle exchange information on replacing nozzles included in the head with other nozzles; and
a moving distance of the head between a board and a slot in which a feeder is provided among the plurality of slots.

19. The method for mounting a component of claim 18, wherein the determining the predicted task time further comprises:
generating a first algorithm in which the plurality of components are adsorbed to a maximum number of nozzles;
generating a second algorithm in which a minimum number of nozzles are exchanged;
generating a third algorithm in which the moving distance of the head is a minimum; and
determining the predicted task time according to the first algorithm, the second algorithm, and the third algorithm.

20. The method for mounting a component of claim 18, wherein the determining of the predicted task time further comprises determining the predicted task time based on the disposition information of the feeders among the plurality of slots and to at least one of the simultaneous adsorption information, the nozzle exchange information, and the moving distance of the head.
